(19) United States
(12) Patent Application Publication
(10) Pub. No.: US 2014/0242810 A1
(43) Pub. Date: Aug. 28, 2014

(54) SUBSTRATE PROCESSING APPARATUS AND METHOD OF SUPPLYING AND EXHAUSTING GAS

(71) Applicant: Hitachi Kokusai Electric Inc., Tokyo (JP)

(72) Inventor: Sataoshi TAKANO, Toyama-shi (JP)

(73) Assignee: HITACHI KOKUSAI ELECTRIC, INC., Tokyo (JP)

(21) Appl. No.: 14/191,064

(22) Filed: Feb. 26, 2014

(30) Foreign Application Priority Data
Feb. 27, 2013 (JP) 2013-037121

(51) Int. Cl. H01L 21/02

(52) U.S. Cl. CPC H01L 21/02282
USPC 438/782; 118/730

(57) ABSTRACT

A substrate processing apparatus includes: a process chamber for processing a substrate; a substrate mounting member including a mounting surface on which a plurality of substrates are concentrically mounted with facing a ceiling of the process chamber; a rotation instrument for rotating the substrate mounting member in a direction parallel to the mounting surface; a gas supply unit and a gas exhaust unit which are disposed in the process chamber above the substrate mounting member upstream and downstream in the substrate mounting member rotating direction, respectively; and a controller for controlling the gas supply unit, the gas exhaust unit, and the rotation instrument to process the substrates, when the substrate passes through a predetermined region formed in the process chamber by the gas supply unit and the gas exhaust unit, by supplying a reactant gas from the gas supply unit and exhausting the reactant gas from the gas exhaust unit.

### BACKGROUND

1. Technical Field

The present invention relates to a method of manufacturing a semiconductor device including a substrate processing process and a substrate processing apparatus that performs processes according to a method of supplying and exhausting gas.

2. Related Art

For example, a substrate processing process that forms a thin film on a substrate is performed as one process of a method of manufacturing a semiconductor device such as a flash memory or a dynamic random access memory (DRAM). A thin film deposition apparatus, including a reaction chamber that forms the thin film on a plurality of substrates mounted on a substrate mounting member, is known as a substrate processing apparatus that performs the substrate processing process (see JP 2008-524842 A).

However, in the apparatus having a structure of the conventional art, there is a difference in an amount of processing gas supplied to the substrate between portions near and far from a processing gas supply unit which is disposed above the center of the substrate mounting member on which a plurality of substrates are mounted. Specifically, the gas concentration in the portion near the processing gas supply unit is high and the gas concentration is decreased toward a periphery of the substrate mounting member. As a result, since a film thickness formed on the substrate in the portion near the processing gas supply unit is increased as compared to the periphery of the substrate mounting member, there is a problem that the film thickness deposited on the surface of the substrate is uneven.

### SUMMARY

Accordingly, it is an object of the present invention to provide a technique in which the concentration of a processing gas supplied to a substrate is to be uniform across a surface of the substrate mounted on a substrate mounting member.

According to one aspect of the present invention, there is provided a substrate processing apparatus, including: a process chamber configured to process a substrate; a substrate mounting member including a mounting surface which is configured to concentrically mount a plurality of substrates and faces a ceiling of the process chamber; a rotation instrument configured to rotate the substrate mounting member in a direction parallel to the mounting surface; a gas supply unit disposed in the process chamber above the substrate mounting member upstream in a rotation direction of the substrate mounting member; a gas exhaust unit disposed in the process chamber above the substrate mounting member downstream in the substrate mounting member rotating direction; and a controller configured to control the gas supply unit, the gas exhaust unit, and the rotation instrument so as to process the substrate, when the substrate passes through a predetermined region formed in the process chamber by the gas supply unit and the gas exhaust unit, by supplying a reactant gas from the gas supply unit and exhausting the reactant gas from the gas exhaust unit.

According to another aspect of the present invention, there is provided a method of manufacturing a semiconductor device including: concentrically mounting a plurality of substrates on a substrate mounting member disposed in a process chamber with a plurality of partitioned regions; rotating the plurality of the concentrically mounted substrates; and in a region in which a gas flow direction from the gas supply unit to the gas exhaust unit is the same as the rotation direction of the substrate mounting member, supplying a reactant gas from a gas supply unit which is disposed at a position facing the substrate mounting member upstream in a rotation direction of the substrate mounting member, and exhausting the reactant gas from a gas exhaust unit which is disposed at a position facing the substrate mounting member downstream in the rotation direction of the substrate mounting member to process the substrate.

According to yet another aspect of the present invention, there is provided a method of supplying and exhausting gas including: concentrically mounting a plurality of substrates on a substrate mounting member disposed in a process chamber with a plurality of partitioned regions; rotating the plurality of the concentrically mounted substrates; and in a region in which a gas flow direction from the gas supply unit to the gas exhaust unit is the same as the rotation direction of the substrate mounting member, supplying a reactant gas from a gas supply unit which is disposed at a position facing the substrate mounting member upstream in a rotation direction of the substrate mounting member, and exhausting the reactant gas from a gas exhaust unit which is disposed at a position facing the substrate mounting member downstream in the rotation direction of the substrate mounting member.

According to the present invention having the above-described structure, it is possible to prevent the concentration of the process gas supplied to the substrate from becoming uneven.

### BRIEF DESCRIPTION OF DRAWINGS

FIG. 1 is a view schematically illustrating a substrate processing apparatus according to the present invention;

FIG. 2 is a view schematically illustrating the substrate processing apparatus according to the present invention;

FIG. 3 is a view for explaining a substrate process chamber according to the present invention;

FIG. 4 is a view for explaining a substrate process chamber according to the present invention;

FIG. 5 is a view for explaining a substrate process chamber according to the present invention;

FIG. 6 is a view for explaining a substrate process chamber according to the present invention;

FIG. 7 is a flowchart for explaining a substrate processing process according to the present invention; and

FIG. 8 is a flowchart for explaining a film forming process according to the present invention.

### DETAILED DESCRIPTION

### First Embodiment

### (1) Configuration of Substrate Processing Apparatus

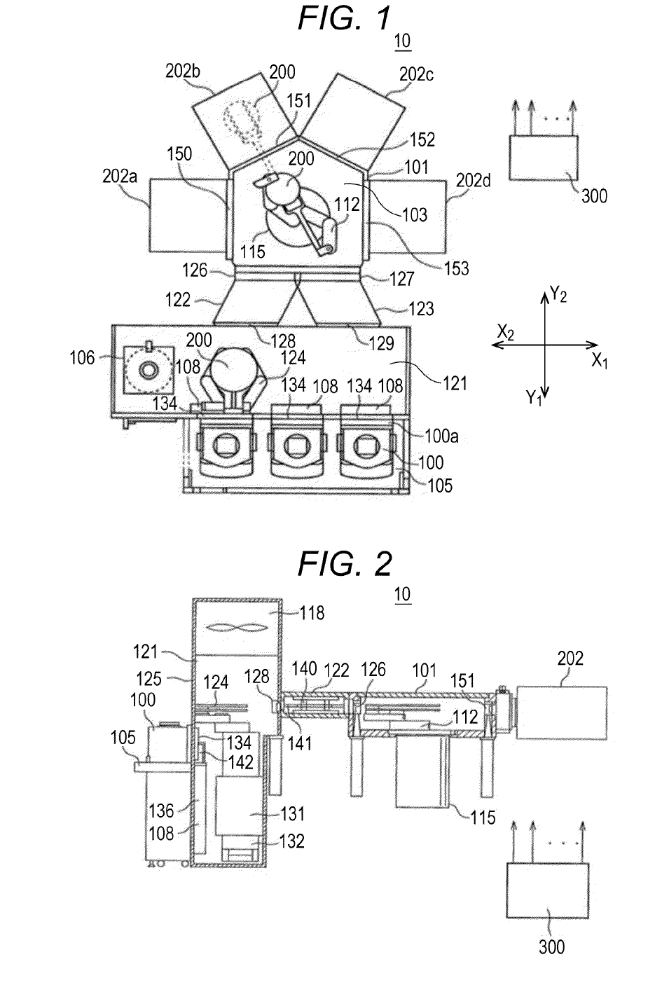

First, a configuration of a substrate processing apparatus according to a first embodiment will be described with reference to FIG. 1. FIG. 1 is a view schematically illustrating a multi-sheet type substrate processing apparatus 10 according to the first embodiment.

A schematic configuration of the substrate processing apparatus according to the first embodiment will be described with reference to FIGS. 1 and 2.

Moreover, in the substrate processing apparatus according to the first embodiment, a front opening unified pod (FOUP, hereinafter referred to as pod) is used as a carrier that transfers a substrate such as a processing substrate 200 as a product. Also, for convenience of a description below, front, rear, left and right are defined on the basis of FIG. 1. That is, an X1 direction is referred to as the right, an X2 direction is referred to as the left, a Y1 direction is referred to as the front, and a Y2 direction is referred to as the rear as shown in FIG. 1.

As shown in FIGS. 1 and 2, the substrate processing apparatus includes a first transfer chamber 103 that is configured in a load lock chamber structure capable of withstanding a pressure (subatmospheric pressure) less than an atmospheric pressure such as a vacuum state. A main body 101 of the first transfer chamber 103 has, for example, a pentagonal shape when seen from a plane, and has a box shape in which both a lower end and an upper end are closed. A first substrate transfer robot 112 that can simultaneously transfer two substrates 200 under subatmospheric pressure is disposed in the first transfer chamber 103. Herein, the first substrate transfer robot 112 may be a device that can transfer one substrate 200. The first substrate transfer robot 112 may ascend and descend while maintaining the sealability of the first transfer chamber 103 by using a first substrate transfer elevator 115.

Auxiliary chambers 122 and 123, which can be used both as an auxiliary chamber for loading and an auxiliary chamber for unloading and have a structure capable of withstanding subatmospheric pressure, respectively, are connected to two side walls disposed in the front side among five side walls of the main body 101 through gate valves 126 and 127, respectively. Furthermore, it is possible to put two substrates 200 so as to be stacked in the auxiliary chamber (load lock chamber) 122 and the auxiliary chamber (load lock chamber) 123 by a substrate support member 140.

A partition wall plate (middle plate) 141 may be disposed between substrates in the auxiliary chambers 122 and 123. Therefore, when a plurality of processed substrates are loaded into the auxiliary chamber 122 or 123, the cooling speed of a first-loaded processed substrate can be prevented from being slowed thermal interference in spite of the heat of a next-loaded processed substrate by the partition wall plate.

Herein, a general method for increasing cooling efficiency will be described. Cooling water, coolant, or the like flows in the auxiliary chambers 122 and 123, and the partition wall plate 141. By providing the above-described structure, it is possible to keep down a temperature of the wall surface, and increase the cooling efficiency even if the processed substrate enters any slot. If a distance between the substrate and the partition wall plate is too far away in subatmospheric pressure, the cooling efficiency is decreased due to a heat exchange occurring therebetween. Therefore, as a method of improving the cooling efficiency, a drive instrument may be provided for vertically moving a substrate support member (pin) to bring it close to the wall surface of the auxiliary chamber after a substrate is placed on the substrate support member.

A second transfer chamber 121 which is used under a substantially atmospheric pressure is connected to a front side of the auxiliary chambers 122 and 123 through gate valves 128 and 129. A second substrate transfer robot 124 is disposed in the second transfer chamber 121 to transfer the substrate 200. The second substrate transfer robot 124 may be ascended and descended by a second substrate transfer elevator 131 disposed in the second transfer chamber 121, and may be reciprocally moved in a lateral direction by a linear actuator 132.

As shown in FIG. 1, a notch or an orientation flat alignment apparatus 106 may be disposed on the left side of the second transfer chamber 121. Furthermore, as shown in FIG. 2, a clean unit 118 that supplies clean air may be disposed at an upper portion of the second transfer chamber 121.

As shown in FIGS. 1 and 2, a substrate loading/unloading entrance 134 through which the substrate 200 is loaded/unloaded to the inside or outside of the second transfer chamber 121, and a pod opener 108 are disposed in the front side of a main body 125 of the second transfer chamber 121. A load port (input/output (I/O) stage) 105 is disposed in a side opposite to the pod opener 108 with the substrate loading/unloading entrance 134 therebetween, that is the outside of the main body 125. The pod opener 108 includes a closure 142 that can open and close a cap 100a of a pod 100 and close the substrate loading/unloading entrance 134, and a drive instrument 136 that drives the closure 142. The substrate 200 may be received or unloaded into the pod 100 by opening or closing the cap 100a of the pod 100 mounted on the load port 105. Also, the pod 100 allows the substrate 200 to be loaded (supplied) and unloaded (discharged) into and from the load port 105 by an in-process transfer device (such as OHT, not shown).

As shown in FIG. 1, a processing furnace (process chamber) 202 that performs a desired processing to the substrate is installed in four side walls that are disposed in the rear side (back side) among five side walls that form the main body 101 containing the first transfer chamber 103. Specifically, a first processing furnace 202a, a second processing furnace 202b, a third processing furnace 202c, and a fourth processing furnace 202d are connected to the main body 101 containing the first transfer chamber 103 through gate valves 150, 151, 152 and 153, respectively.

Hereinafter, a substrate processing process using the substrate processing apparatus having the above-described configuration will be described. As shown in FIGS. 1 and 2, the operation of the following components is controlled by a controller 300. In the above configuration, the controller 300 controls the entire apparatus.

In a state in which a maximum of 25 substrates 200 are loaded on the pod 100, the substrates 200 are transferred into the substrate processing apparatus that performs the processing process by the in-process transfer device. As shown in FIGS. 1 and 2, the transferred substrate 200 is delivered and mounted on the load port 105 from the in-process transfer device. The cap 100a of the pod 100 is removed by the pod opener 108 and a receiving/unloading entrance of the pod 100 is opened.

After the pod 100 is opened by the pod opener 108, the second substrate transfer robot 124 disposed in the second transfer chamber 121 picks up the substrate 200 from the pod 100. Furthermore, the substrate 200 is loaded into the auxiliary chamber 122 by the second substrate transfer robot 124 and the substrate 200 is transferred to the substrate support member 140. During this transfer operation, the gate valve 126 of the first transfer chamber 103 side of the auxiliary chamber 122 is closed, and thereby the first transfer chamber 103 is maintained with subatmospheric pressure. When the transferring to the substrate support member 140 completes the substrate 200 stored by the pod 100, the gate valve 128 is closed, and the inside of the auxiliary chamber 122 is exhausted by an exhaust device (not shown) to reach a subatmospheric pressure.

When a pressure in the auxiliary chamber 122 is reduced to a predetermined pressure, the gate valve 126 is opened such that the auxiliary chamber 122 communicates with the first transfer chamber 103. Subsequently, the first substrate transfer robot 112 disposed in the first transfer chamber 103 picks up the substrate 200 from the substrate support member 140 and loads the substrate 200 into the first transfer chamber 103. After the gate valve 126 is closed, a gate valve 151 is opened to communicate the first transfer chamber 103 with the second processing furnace 202b. After the gate valve 151 is closed, a processing gas is supplied into the processing furnace 202 and a desired processing is performed on the substrate 200.

When processing for the substrate 200 is completed in the second processing furnace 202b, the gate valve 151 is opened, and the substrate 200 is unloaded into the first transfer chamber 103 by the first substrate transfer robot 112. After unloading, the gate valve 151 is closed.

Subsequently, the gate valve 127 is opened, and the substrate 200 which has been unloaded from the second processing furnace 202b is transferred to the substrate support member 140 by the first substrate transfer robot 112 so as to cool the processed substrate 200.

When the processed substrate 200 is transferred into the auxiliary chamber 123, and a predetermined cooling time has passed, the auxiliary chamber 123 is returned to a substantially atmospheric pressure by an inert gas. When the inside of the auxiliary chamber 123 is returned to a substantially atmospheric pressure, the gate valve 129 is opened, and the cap 100a of the empty pod 100 which is placed on the load port 105 is opened by the pod opener 108.

Subsequently, the substrate 200 is transferred from the substrate support member 140 into the second transfer chamber 121 by the second substrate transfer robot 124 of the second transfer chamber 121, and then placed in the pod 100 through the substrate loading/unloading entrance 134 of the second transfer chamber 121.

Herein, the cap 100a of the pod 100 may stay open until a maximum of 25 substrates are loaded back in the pod 100. The substrate may be loaded back in the pod 100 from which the substrate is unloaded instead of an empty pod 100.

When all of the 25 processed substrates 200 are placed in the pod 100 by repeatedly performing the above-described operations, the cap 100a of the pod 100 is closed by the pod opener 108. The closed pod 100 is transferred from the load port 105 to a next process by the in-process transfer device.

In the above-described operations, a case of using the second processing furnace 202b, the auxiliary chamber 122 and the auxiliary chamber 123 has been described as an example, but the same operation may be performed in a case in which the first processing furnace 202a, the third processing furnace 202c, and the fourth processing furnace 202d are used.

In addition, although a case of using the four process chambers has been described in the present embodiment, the number of the process chambers may be determined depending on the corresponding substrate and on the type of the film formed thereon.

Furthermore, in the above-described substrate processing apparatus, the auxiliary chamber 122 is used for loading and the auxiliary chamber 123 is used for unloading, but the auxiliary chamber 123 may be used for loading and the auxiliary chamber 122 may be used for unloading, and the auxiliary chambers 122 and 123 may both be used for loading and for unloading.

When the auxiliary chamber 122 or the auxiliary chamber 123 is exclusively used for loading and unloading, it is possible to reduce cross-contamination. While, the auxiliary chambers 122 and 123 both are used for loading and for unloading, it is possible to improve transfer efficiency of the substrate.

In addition, all of the processing furnaces may perform the same process, or respective processing furnaces may perform different processes. For example, in a case where the first and second processing furnaces 202a and 202b are subjected to different processes, the first processing furnace 202a may perform a certain process on the substrate 200, and then the second processing furnace 202b may perform another process on the substrate 200. Also, in a case where the first processing furnace 202a performs a certain process on the substrate 200 and then the second processing furnace 202b performs another process on the substrate 200, the substrate 200 may pass through the auxiliary chamber 122 or the auxiliary chamber 123.

Furthermore, the processing furnace may be formed by connecting at least one of the processing furnaces 202a and 202b at one place, or connecting the processing furnaces 202c and 202d at two places, therefore, the process chamber may be formed by connecting processing furnace 202a to processing furnace 202d at a total of up to four places, if it is a possible combination thereof.

In addition, the number of substrates to be processed in the apparatus is not limited, and one substrate may be processed and a plurality of substrates may be processed. Similarly, even one substrate may be cooled and a plurality of substrates may be cooled in the auxiliary chamber 122 or 123. The number of the processed substrates to be cooled is also not limited, and may be cooled in any combination if it is within a range of a maximum of five substrates that can be introduced into the slots of the auxiliary chambers 122 and 123.

Furthermore, during loading the processed substrate in the auxiliary chamber 122 to cool the same, the substrate may be loaded in the processing furnace by opening and closing the gate valve of the auxiliary chamber 122 to process the substrate therein. Similarly, during loading the processed substrate in the auxiliary chamber 123 to cool the same, the substrate may be loaded in the processing furnace by opening and closing the gate valve of the auxiliary chamber 123 to process the substrate therein.

Herein, if the gate valves 128 and 129 on a substantially atmospheric side are opened without undergoing sufficient cooling time, electrical components connected the auxiliary chamber 122, the auxiliary chamber 123, or around thereof may be damaged due to radiation heat of the substrate 200. Therefore, when cooling a hot substrate, during loading the processed substrate having a large radiation heat in the auxiliary chamber 122 to cooling the same, the substrate may be loaded in the processing furnace by opening and closing the gate valve of the auxiliary chamber 123 to process the substrate therein. Similarly, during loading the processed substrate in the auxiliary chamber 123 to cool the same, the substrate may be loaded in the processing furnace by opening and closing the gate valve of the auxiliary chamber 122 to process the substrate therein.

### (2) Configuration of Process Chamber

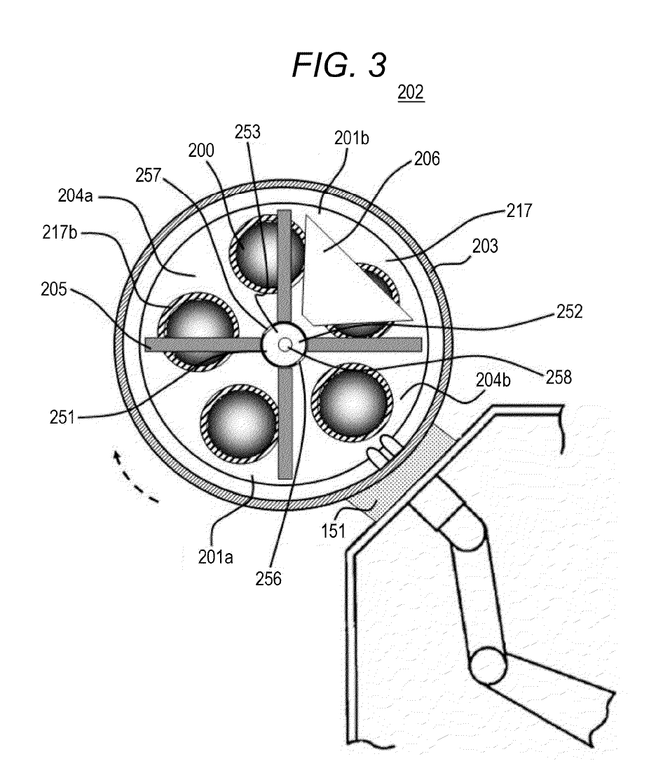

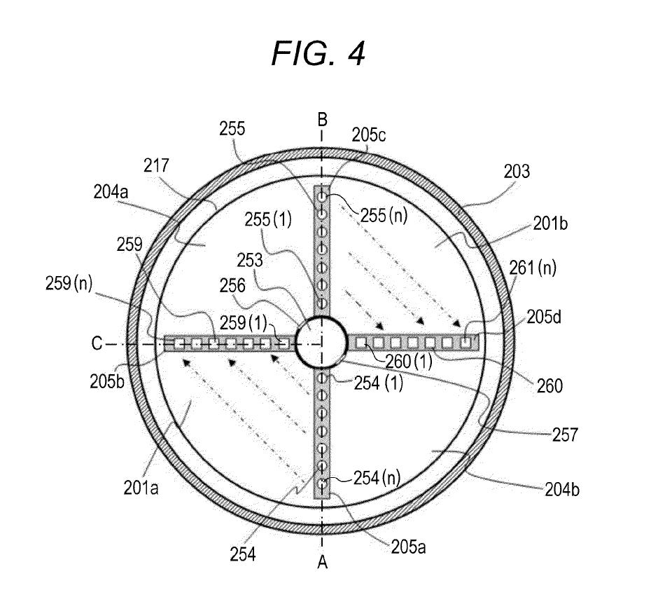

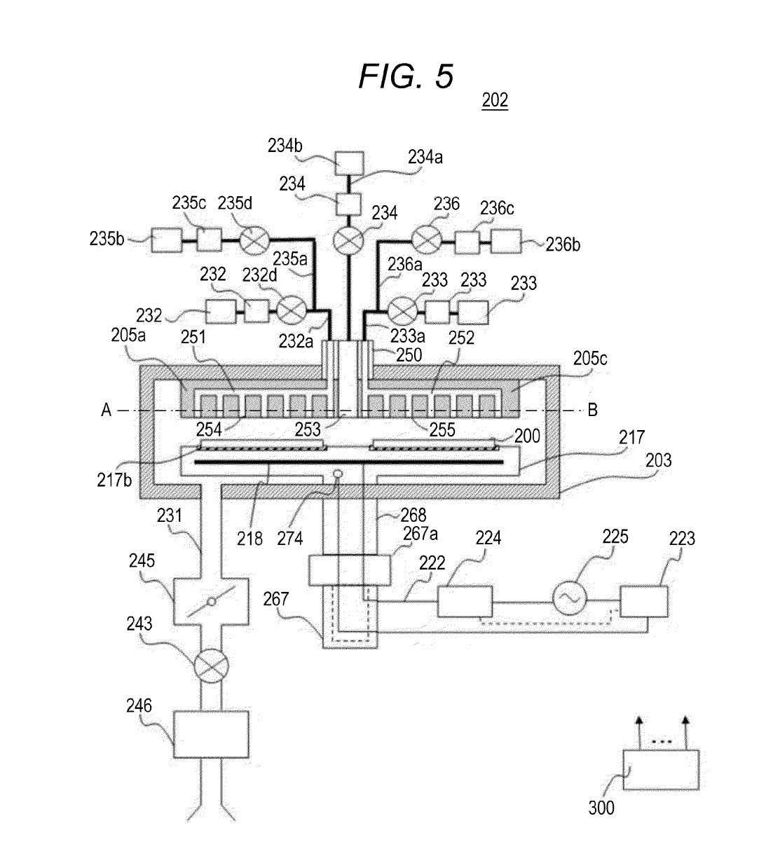

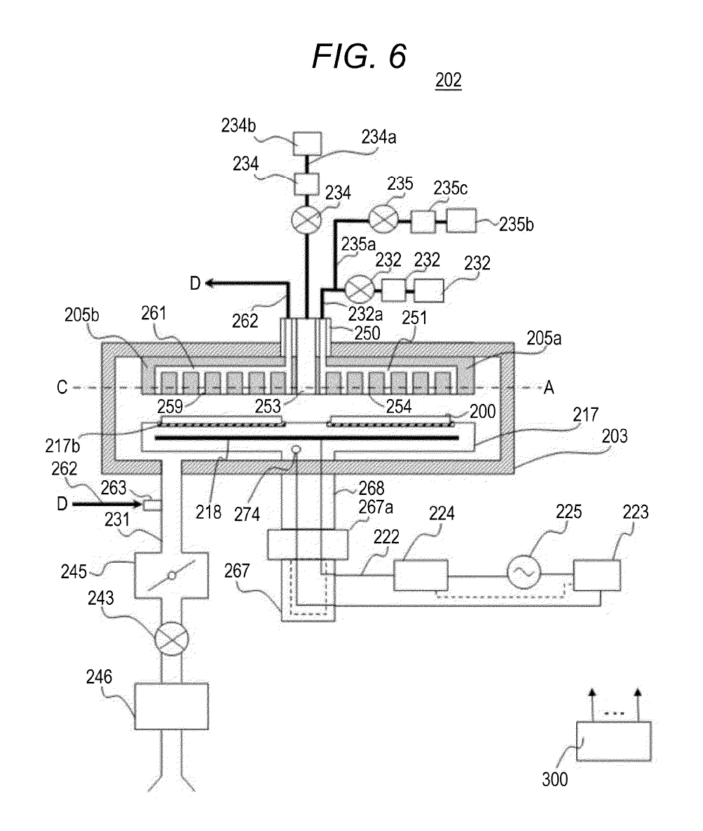

Subsequently, the configuration of a process chamber 202 as the processing furnace according to the first embodiment will be described mainly with reference to FIGS. 3 to 6. The process chamber 202 may be the first processing furnace 202a. FIG. 3 is a cross-sectional view schematically illustrating a processing furnace according to the first embodiment, FIG. 4 is a view for explaining a specific structure of the processing furnace according to the first embodiment, FIG. 5 is a longitudinal sectional view taken along line A-B in FIG. 4, and FIG. 6 is a longitudinal sectional view taken along line A-C in FIG. 4.

(Reaction Container)

As shown in FIGS. 3 to 6, the process chamber 202 as the processing furnace includes a reaction container 203 which is a cylindrical sealing container. A process chamber as a processing space 207 for the substrate 200 is formed in the reaction container 203. Four partition plates 205, which are extended in a radial direction from the central portion of the reaction container 203, are disposed at an upper side of the processing space 207 in the reaction container 203. The four partition plates 205, as a partition part, partition the processing space 207 in the reaction container 203 into four regions, that is, a first processing region 201a, a first purge region 204a, a second processing region 201b, and a second purge region 204b. That is, the processing regions and the purge regions are arranged adjacent to each other through the four partition plates 205.

The first processing region 201a, the first purge region 204a, the second processing region 201b, and the second purge region 204b are arranged in this order in a rotation direction of a susceptor (substrate mounting member) 217 to be described below.

Specifically, the partition plates 205 are arranged as follows.

A partition plate 205a is disposed upstream of the first processing region 201a and between the first processing region 201a and the second purge region 204b. A partition plate 205b is disposed downstream of the first processing region 201a and between the first processing region 201a and the first purge region 204a. A partition plate 205c is disposed upstream of the second processing region 201b and between the first purge region 204a and the second processing region 201b. A partition plate 205d is disposed downstream of the second processing region 201b and between the second processing region 201b and the second purge region 204b.

As described below, by rotating the susceptor 217, a substrate 200 mounted on the susceptor 217 is moved through the first processing region 201a, the first purge region 204a, the second processing region 201b, and the second purge region 204b in this order. Also, as described below, a first processing gas, as a first gas (reactant gas), is supplied into the first processing region 201a, a second processing gas, as a second gas (reactant gas), is supplied into the second processing region 201b, and an inert gas (non-reactant gas) is supplied into the first and second purge regions 204a and 204b. Therefore, by rotating the susceptor 217, the first processing gas, the inert gas, the second processing gas, and the inert gas are supplied onto the substrate 200 in this order. The configuration of the susceptor 217 and the gas supply system will be described below.

A gap having a predetermined width is formed between an end portion of the partition plate 205 and a side wall of the reaction container 203 and between a bottom of the partition plate 205 and the substrate mounting member (susceptor) 217, and a gas passes through the gap. The inert gas is jetted from inside the first and second purge regions 204a and 204b into the first and second processing regions 201a and 201b through the gap. Therefore, the processing gas may be prevented from entering into the first and second purge regions 204a and 204b, and thus, a reaction by mixing of the processing gases may be prevented.

Moreover, in the first embodiment, an angle between adjacent partition plates 205 is 90°, but the present invention is not limited thereto. That is, in consideration of a time that is taken in supplying various gases to the substrate 200, for example, an angle between two partition plates 205 forming the second processing region 201b may be relatively greater, or may be appropriately changed. Preferably, in the present embodiment, in order to form a flow of the reactant gas so as to be a forward direction with respect to the rotational direction of the substrate 200, an angle between two partition plates 205 forming the processing region (first and second processing regions 201a and 201b) is less than 90°. Furthermore, it is preferable to supply the inert gas into a non-processing region (first and second purge region 204a and 204b). With this configuration, not only separating the first processing gas and the second processing gas, but also forming a flow of the reactant gas (first and second reactant gases) so as to be a forward direction with respect to the rotational direction of the substrate 200 may be easily achieved. Furthermore, it is also preferable that an angle between two partition plates 205 forming the non-processing region (first and second purge regions 204a and 204b) is greater than 90°.

In addition, although the respective regions are partitioned by the partition plates 205, the present invention is not limited thereto, and may be formed to be so as not to mix the gas supplied to each of the processing regions 201a and 201b.

(Susceptor)

As shown in FIGS. 3 to 6, the susceptor 217 is disposed at the center of a lower side of the reaction container 203 below the partition plate 205. The susceptor 217, as the substrate mounting member, is rotatable about a rotation axis that is located at the center of the reaction container 203. The susceptor 217, for example, may be made of a nonmetal material such as carbon (C), aluminum nitride (AlN), ceramics, quartz, or the like, in order to reduce the metal pollution for the substrate 200. If it is not considering the metal contamination in the substrate processing, the susceptor 217 may be made of aluminum (Al). Also, the susceptor 217 is electrically insulated from the reaction container 203.

The susceptor 217 supports a plurality of substrates 200 (for example, five substrates in the first embodiment) on the same plane and on the same circumference, in the reaction container 203. Herein, the same plane is not limited to the completely same plane and, when seen from a top of the susceptor 217, as shown in FIGS. 3 and 4, the plurality of substrates 200 may be arranged not to be overlapped with each other. In this way, the susceptor 217 has a mounting surface on which the plurality of the substrates 200 is mounted concentrically thereto, such that the mounting surface faces a ceiling of the reaction container 203.

Also, a substrate mounting portion 217b is formed on the susceptor 217 at a position supporting the substrate 200 corresponding to the number of the substrates 200 to be processed. The substrate mounting portion 217b may have a circular shape when seen from the top and a concave shape when seen from a side. In this case, the substrate mounting portion 217b may be formed to have a diameter slightly greater than that of the substrate 200. By disposing the substrate 200 in the substrate mounting portion 217b, the position of the substrate 200 can be easily determined. Furthermore, when the susceptor 217 rotates, a centrifugal force is applied to the substrate 200. However, due to the substrate 200 disposed in the substrate mounting portion 217b, even if the centrifugal force is applied to the substrate 200, the deviation of the position of the substrate 200 that occurs in a case of jumping out the substrate 200 from the susceptor 217 may be prevented.

An elevating instrument 268 that ascends and descends the susceptor 217 is disposed in the susceptor 217. A plurality of through holes (not shown) is formed in the susceptor 217. A plurality of substrate lift pins is disposed at a bottom of the reaction container 203. When the substrate 200 is loaded into or unloaded from the reaction container 203, the substrate lift pins lift the substrate 200 and support a backside of the substrate 200. The through holes and the substrate lift pins are arranged such that the substrate lift pins pass through the respective through holes without contacting the susceptor 217 when the substrate lift pins are lifted or the susceptor 217 is lowered by the elevating instrument 268.

A rotation instrument 267 for rotating the susceptor 217 is disposed in the elevating instrument 268. A rotation axis (not shown) of the rotation instrument 267 is connected to the susceptor 217. The susceptor 217 rotates in a direction parallel to the mounting surface of the susceptor 217 by driving the rotation instrument 267. The controller 300 to be described below is connected to the rotation instrument 267 through a coupling member 267a. The coupling member 267a is a slip ring instrument that electrically connects a rotation axis and a fixed axis by using a metal brush or the like. Therefore, the rotation of the susceptor 217 is not disturbed. The controller 300 controls an electrical connection to the rotation instrument 267 such that the susceptor 217 rotates at a predetermined speed for a predetermined time. As described above, by rotating the susceptor 217, a substrate 200 mounted on the susceptor 217 sequentially moves through the first processing region 201a, the first purge region 204a, the second processing region 201b, and the second purge region 204b in this order.

(Heating Unit)

A heater 218, as a heating unit, is buried integrally in the susceptor 217 to heat the substrate 200. When power is supplied to the heater 218, a surface of the substrate 200 mounted on the substrate mounting portion 217b is heated to a predetermined temperature (for example, a room temperature to about 1,000° C.). Also, a plurality of (for example, five) heaters 218 may be disposed on the same plane so as to respectively heat a plurality of substrates 200 mounted on the susceptor 217.

A temperature sensor 274 is disposed in the susceptor 217. The heater 218 and the temperature sensor 274 are electrically connected to a temperature adjustor 223, a power adjustor 224, and a heater power source 225 through a power supply line 222. An electrical conduction to the heater 218 is controlled on the basis of temperature information detected by the temperature sensor 274.

(Gas Supply Unit)

A gas supply unit 250, which includes a first processing gas introduction instrument 251, a second processing gas introduction instrument 252, and an inert gas introduction instrument 253, is disposed in an upper side of the reaction container 203. The gas supply unit 250 arranged above the susceptor 217 is air-tightly disposed in an opening that is formed in the upper side of the reaction container 203. The first processing gas introduction instrument 251 is disposed in the partition plate 205a and has a first gas ejection port 254. The second processing gas introduction instrument 252 is disposed in the second partition plate 205c. A second gas ejection port 255 is disposed in a side wall of the inert gas introduction instrument 253. A first inert gas ejection port 256 and a second inert gas ejection port 257 are disposed to face each other in the side wall of the inert gas introduction instrument 253, respectively.

The first gas ejection port 254 has a plurality of first gas ejection holes 254(1) to 254(n) which are holes for ejecting gas and is disposed in a lower portion of the partition plate 205a. That is, the first gas ejection port 254 is disposed above the susceptor 217 so as to face a wafer 200 mounted thereon.

Among the plurality of first gas ejection ports 254, a distance between the first gas ejection hole 254(1) which is arranged at a position nearest to the center of the susceptor 217 and the first gas ejection hole 254(n) which is arranged at a position nearest to a peripheral edge side of the susceptor 217 is larger than a diameter of the wafer. That is, a width of the first gas ejection port 254 is larger than the diameter of the wafer.

The second gas ejection port 255 has a plurality of second gas ejection holes 255(1) to 255(n) which are holes for ejecting gas and is disposed in a lower portion of the partition plate 205c. That is, the second gas ejection port 255 is disposed above the susceptor 217 so as to face the wafer 200 mounted thereon.

Among the plurality of second gas ejection ports 255, a distance between the second gas ejection hole 255(1) which is arranged at a position nearest to the center of the susceptor 217 and the second gas ejection hole 255(n) which is arranged at a position nearest to a peripheral edge side of the susceptor 217 is larger than the diameter of the wafer. That is, a width of the second gas ejection port 255 is larger than the diameter of the wafer.

The gas supply unit 250 supplies a first processing gas into the first processing region 201a through the first processing gas introduction instrument 251, a second processing gas into the second processing region 201b through the second processing gas introduction instrument 252, and an inert gas into the first and second purge regions 204a and 204b through the inert gas introduction instrument 253. The gas supply unit 250 may separately supply the first and second gases and the inert gas without mixing the first and second processing gases and the inert gas to the respective regions. Also, the gas supply unit 250 may supply the first and second processing gases and the inert gas at the same time to the respective regions.

A first gas supply pipe 232a is connected to an upstream side of the first processing gas introduction instrument 251. A raw material gas supply source 232b, a mass flow controller (MFC) 232c that is a flow rate controller (flow rate control unit), and a valve 232d of an opening and closing valve are disposed in this order from an upstream side of the first gas supply pipe 232a.

The first gas (first processing gas) such as a silicon-containing gas is supplied from the first gas supply pipe 232a into the first processing region 201a through the MFC 232c, the valve 232d, the first processing gas introduction instrument 251, and the first gas ejection port 254. The silicon-containing gas such as trisilylamine ((SiH₃)₃N, TSA) gas may also be used as a precursor of the first processing gas. Also, the first processing gas may be one of solid, liquid, and gas at a room temperature and a normal pressure, and will be described as gas herein. When the first processing gas is liquid at the room temperature under the normal pressure, a vaporizer (not shown) may be disposed between the raw material gas supply source 232b and the MFC 232c.

Moreover, in addition to TSA, hexamethyldisilazane (C₆H₁₉NSi₂, HMDS), trisdimethylaminosilane (Si[N(CH₃)₂]₃H, 3DMAS), bis tertiary-butylaminosilane (SiH₂(NH(C₄H₉))₂, BTBAS), or the like, that is an organic silicon material may also be used as the silicon-containing gas.

The first gas may use a material having a higher degree of adhesion than the second gas to be described below.

A second gas supply pipe 233a is connected to an upstream side of the second processing gas introduction instrument 252. A raw material gas supply source 233b, a mass flow controller (MFC) 233c that is a flow rate controller (flow rate control unit), and a valve 233d of an opening and closing valve are disposed in this order from an upstream side of the second gas supply pipe 233a.

The second gas (second processing gas, reactant gas) such as oxygen (O₂) gas, which is an oxygen-containing gas, is supplied from the second gas supply pipe 233a into the second processing region 201b through the MFC 233c, the valve 233d, the second processing gas introduction instrument 252, and the second gas ejection port 255. The oxygen gas, which is the second processing gas, is changed into a plasma state by a plasma generating unit 206, and supplied to the substrate 200. Also, the oxygen gas, which is the second processing gas, may be activated with heat by adjusting a temperature of the heater 218 and a pressure in the reaction container 203 to within a predetermined range. Moreover, ozone (O₃) gas or vapor (H₂O) gas may also be used as the oxygen-containing gas.

The second gas may use a material having a low degree of adhesion than the first gas.

A first processing gas supply unit (silicon-containing gas supply system) 232 mainly includes the first gas supply pipe 232a, the MFC 232c, and the valve 232d. Also, the first processing gas supply unit 232 may include the raw material gas supply source 232b, the first processing gas introduction instrument 251, and the first gas ejection port 254.

A second processing gas supply unit (oxygen-containing gas supply system) 233 mainly includes the second gas supply pipe 233a, the MFC 233c, and the valve 233d. Also, the second processing gas supply unit 233 may include the raw material gas supply source 233b, the second processing gas introduction instrument 252, and the second gas ejection port 255. Furthermore, the processing gas supply unit mainly includes the first processing gas supply unit and the second processing gas supply unit.

(Inert Gas Supply Unit)

A first inert gas supply pipe 234a is connected to an upstream side of the inert gas introduction instrument 253. An inert gas supply source 234b, a mass flow controller (MFC) 234c that is a flow rate controller (flow rate control unit), and a valve 234d of an opening and closing valve are disposed in this order from an upstream side of the first inert gas supply pipe 234a.

The inert gas such as nitrogen (N₂) gas is supplied from the first inert gas supply pipe 234a into the first and second purge regions 204a and 204b through the MFC 234c, the valve 234d, the inert gas introduction instrument 253, the first inert gas ejection port 256, and the second inert gas ejection port 257. The inert gas that is supplied into the first and second purge regions 204a and 204b acts as a purge gas in a film forming process S106 to be described below. Also, as the inert gas, a rare gas such as helium (He) gas, neon (Ne) gas, argon (Ar) gas, or the like may also be used in addition to the nitrogen (N₂) gas.

A downstream end of a second inert gas supply pipe 235a is connected to a downstream side from the valve 232d of the first gas supply pipe 232a. An inert gas supply source 235b, amass flow controller (MFC) 235c that is a flow rate controller (flow rate control unit), and a valve 235d of an opening and closing valve are disposed in this order from the upstream side of the second inert gas supply pipe 235a.

The inert gas such as N₂ gas is supplied from the second inert gas supply pipe 235a into the first processing region 201a through the MFC 235c, the valve 235d, the first gas supply pipe 232a, the first processing gas introduction instrument 251, and the first gas ejection port 254. The inert gas that is supplied into the first processing region 201a is used as a carrier gas or a diluent gas in the film forming process S106.

A downstream end of a third inert gas supply pipe 236a is connected to a downstream side from the valve 233d of the second gas supply pipe 233a. An inert gas supply source 236b, amass flow controller (MFC) 236c that is a flow rate controller (flow rate control unit), and a valve 236d of an opening and closing valve are disposed in this order from the upstream side of the third inert gas supply pipe 236a.

The inert gas such as N₂ gas is supplied from the third inert gas supply pipe 236a into the second processing region 201b through the MFC 236c, the valve 236d, the second gas supply pipe 233a, the second processing gas introduction instrument 252, and the second gas ejection port 255. The inert gas that is supplied into the second processing region 201b is used as a carrier gas or a diluent gas in the film forming process S106, similarly to the inert gas that is supplied into the first processing region 201a.

A first inert gas supply unit 234 mainly includes the first inert gas supply pipe 234a, the MFC 234c, and the valve 234d. Also, the first inert gas supply unit 234 may include the inert gas supply source 234b, the inert gas introduction instrument 253, the first inert gas ejection port 256, and the second inert gas ejection port 257.

Also, a second inert gas supply unit 235 mainly includes the second inert gas supply pipe 235a, the MFC 235c, and the valve 235d. Also, the second inert gas supply unit 235 may include the inert gas supply source 235b, the first gas supply pipe 232a, the first processing gas introduction instrument 251, and the first gas ejection port 254.

Also, a third inert gas supply unit 236 mainly includes the third inert gas supply pipe 236a, the MFC 236c, and the valve 236d. Also, the third inert gas supply unit 236 may include the inert gas supply source 236b, the second gas supply pipe 233a, the second processing gas introduction instrument 252, and the second gas ejection port 255. Furthermore, the inert gas supply unit mainly includes the first to third inert gas supply units.

(Gas Supply Unit)

The gas supply unit includes the processing gas supply unit and the inert gas supply unit.

(Gas Exhaust Unit)

As shown in FIGS. 4 to 6, exhaust ports are disposed in the partition plate 205 to exhaust an exhaust gas. Specifically, a plurality of first exhaust ports 259 are formed in the bottom of the partition plate 205d. That is, the first exhaust ports 259 are disposed above the susceptor 217 so as to face the wafer 200 mounted thereon.

Among the plurality of first gas exhaust ports 259, a distance between a first gas exhaust hole 259(1) which is arranged at a position nearest to the center of the susceptor 217 and a first gas exhaust hole 259(n) which is arranged at a position nearest to a peripheral edge side of the susceptor 217 is larger than a diameter of the wafer.

A plurality of second exhaust ports 260 are formed in the bottom of the partition plate 205d. That is, the second exhaust ports 260 are disposed above the susceptor 217 so as to face the wafer 200 mounted thereon.

Among the plurality of second gas exhaust ports 260, a distance between a second gas exhaust hole 260(1) which is arranged at a position nearest to the center of the susceptor 217 and a first exhaust hole 260(n) which is arranged at a position nearest to a peripheral edge side of the susceptor 217 is larger than a diameter of the wafer.

As described below, the first exhaust port 259 exhausts the gas supplied into the first processing region 201a from the first gas ejection port 254, and the second exhaust port 260 exhausts the gas supplied into the second processing region 201b from the second gas ejection port 255.

The gas discharged from the first exhaust port 259 is exhausted, as shown in FIG. 6, by a pump 246 to be described below through a first gas discharge instrument 261 and a first exhaust pipe 262, which are formed in the partition plate 205b.

The gas discharged from the second exhaust port 260 is exhausted, similarly to the first exhaust port 259, by a pump 246 to be described below through a second gas discharge instrument (not shown) and a second exhaust pipe (not shown), which are formed in the partition plate 205d.

An exhaust pipe 231 that exhausts the atmosphere in the processing regions 201a and 201b and the atmosphere in the purge regions 204a and 204b is disposed under the reaction container 203. The first exhaust pipe 262 is connected to the exhaust pipe 231 through a first exhaust pipe connector 263 along line D-D. Furthermore, a second exhaust pipe (not shown) may be connected to the reaction container 203 through a second exhaust pipe connector (not shown).

A vacuum pump 246 which is a vacuum exhaust device is connected to the exhaust pipe 231 through a flow control valve 245 which is a flow rate controller (flow rate control unit) that controls the flow rate of the exhaust gas, and an auto pressure controller (APC) valve 243 which is a pressure adjustor (pressure adjustment unit). Thus, the pressure in the reaction container 203 may be vacuum-exhausted to a predetermined pressure (degree of vacuum). Also, by opening or closing the APC valve 243, it is possible to start or stop the vacuum-exhaust operations at the inside of the reaction container 203. Furthermore, the APC valve 243 adjusts a pressure by changing the degree of the valve's opening. The gas exhaust unit mainly includes the exhaust pipe 231, the APC valve 243, and the flow control valve 245. Also, the vacuum pump 246 may be included in the gas exhaust unit.

(Control Unit)

The operation of the above-described components is controlled by the controller 300 (control unit), respectively.

Next, a structure surrounding the susceptor 217 and an operation of the susceptor 217 will be described with reference to FIGS. 2 and 3.

The main body 101 containing the first transfer chamber 103 is disposed adjacently to the reaction container 203 through any one of gate valves 150 to 153. For example, the inside of the reaction container 203 and the main body 101 of the first transfer chamber 103 are communicated with each other by opening the gate valve 151. The first substrate transfer robot 112 transfers the substrate 200 from the pod 100 to the substrate mounting portion 217b of the susceptor 217 through the second substrate transfer robot 124.

Herein, a plurality of the substrate mounting portions 217b to mount the substrates 200 is formed on the susceptor 217. In the first embodiment, five substrate mounting portions 217b are disposed on the susceptor 217 at a regular interval (interval of 72°, for example) in a clockwise direction. Therefore, when the susceptor 217 is rotated, the five substrate mounting portions 217b are also rotated as a group along an arrow in the clockwise direction.

### (3) Substrate Processing Process

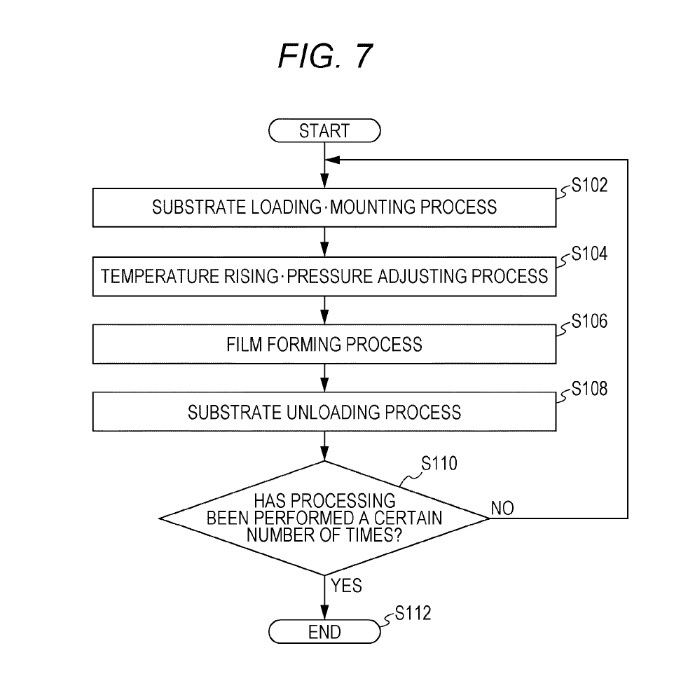

Next, as one process of a method of manufacturing a semiconductor device according to a first embodiment, a substrate processing process that is performed using the process chamber 202b including the above-described reaction container 203 will be described with reference to FIGS. 6 and 7. FIG. 6 is a diagram illustrating the substrate processing process according to the first embodiment. FIG. 7 is a flowchart illustrating the substrate processing operation in a film forming process in the substrate processing process according to the first embodiment. Also, in the following description, the operation of each component of the process chamber 202 of the substrate processing apparatus 10 is controlled by the controller 300.

Herein, the following description will be made on an example that forms a silicon oxide film (SiO₂ film, hereinafter briefly referred to as an SiO film) as an insulation film on a substrate 200 by using the trisilylamine (TSA) gas, which is a silicon-containing gas, as a first processing gas and using the oxygen gas, which is an oxygen-containing gas, as a second processing gas.

(Substrate Loading and Mounting Process 5102)

First, the substrate lift pin 266 ascends to the transfer position of the substrate 200, and the substrate lift pin 266 passes through the through hole (not shown) of the susceptor 217. As a result, the substrate lift pin 266 protrudes from the surface of the susceptor 217 by a predetermined height. Subsequently, the gate valve 151 is opened, and a predetermined number of substrates (processing substrate) 200 (for example, five substrates) are loaded into the reaction container 203 by using the first substrate transfer robot 112. The substrates 200 are mounted about a rotation axis (not shown) of the susceptor 217 not to be overlapped with each other, on the same plane. Therefore, each of the substrates 200 is horizontally supported on the substrate lift pin that protrudes from the surface of the susceptor 217.

When the substrates 200 are loaded into the reaction container 203, the first substrate transfer robot 112 moves outside the reaction container 203, and then, the reaction container 203 is closed by closing the gate valve 151. Subsequently, by lowering the substrate lift pins, the respective substrates 200 are mounted on the substrate mounting portion 217b formed on the susceptor 217, in respective lower portions of the first processing region 201a, the first purge region 204a, the second processing region 201b, and the second purge region 204b.

Moreover, when loading the substrates 200 into the reaction container 203, the inert gas supply unit may supply N₂ gas (which is a purge gas) into the reaction container 203 while the exhaust unit exhausts the inside of the reaction container 203. That is, the inside of the reaction container 203 is exhausted by driving the vacuum pump 246 and opening the APC valve 243. Simultaneously, N₂ gas may be supplied into the reaction container 203 by at least opening the valve 234d of the first inert gas supply unit. Therefore, particles can be prevented from entering the processing region 201, or from being adhered to the substrates 200. Herein, the second inert gas supply unit and the third inert gas supply unit may supply an inert gas. Also, the vacuum pump 246 continuously maintains an operation state until the substrate loading and mounting process S102 to the below-described substrate unloading process S108 are ended.

(Temperature Rising and Pressure Adjusting Process 5104)

Power is supplied to the heater 218 that is buried in the susceptor 217, and the surface of each of the substrates 200 is heated to a predetermined temperature (for example, 200° C. to 400° C.). At this time, the temperature of the heater 218 is adjusted by controlling an electrical conduction to the heater 218 according to temperature information detected by the temperature sensor 274.

Moreover, in heating the substrate 200 formed of silicon, when the surface temperature of the substrate 200 is heated to more than or equal to 750° C., impurities are diffused into a source region or a drain region that is formed at the surface of the substrate 200, circuit characteristics are degraded, and the performance of a semiconductor device is reduced in some cases. By restricting the temperature of the substrate 200 as described above, impurities can be prevented from being diffused into a source region or a drain region that is formed at the surface of the substrate 200, the degradation of the circuit characteristics can be prevented, and the performance of a semiconductor device can be improved.

Moreover, the vacuum pump 246 vacuum-exhausts the inside of the reaction container 203 such that a pressure in the reaction container 203 becomes a desired pressure (for example, 0.1 Pa to 300 Pa, and preferably, 20 Pa to 40 Pa). At this time, the pressure in the reaction container 203 is measured by a pressure sensor (not shown), and the degree of the opening of the APC valve 243 is feedback-controlled on the basis of the measured pressure information.

Moreover, the rotation of the susceptor 217 is started by driving the rotation instrument 267 while heating the substrate 200. At this time, the rotation speed of the susceptor 217 is controlled by the controller 300. The rotation speed of the susceptor 217, for example, may be one rotation/sec. By rotating the susceptor 217, the substrate 200 is moved through the first processing region 201a, the first purge region 204a, the second processing region 201b, and the second purge region 204b, and thus passes through the regions, sequentially.

(Film Forming Process S106)

The following description will be made on an example of a process that forms a SiO film on the substrate 200 by supplying TSA gas as the first processing gas into the first processing region 201a and supplying oxygen gas as the second processing gas into the second processing region 201b. Also, in the following description, the supply of TSA gas, the supply of oxygen gas, and the supply of the inert gas are simultaneously performed to the respective regions.

When the substrate 200 is heated to reach a desired temperature and the susceptor 217 reaches a desired rotation speed, at least the valves 232d, 233d and 234d are opened, and a processing gas and an inert gas are supplied to the processing regions 201 and the purge regions 204, respectively. That is, TSA gas is supplied into the first processing region 201a by opening the valve 232d through the first gas ejection port 254, and oxygen gas is supplied into the second processing region 201b by opening the valve 233d through the second gas ejection port 255. By this, the processing gas is supplied from the processing gas supply unit. Furthermore, N₂ gas which is an inert gas is supplied into the first purge regions 204a and the second purge region 204b by opening the valve 234d, thereby the inert gas is supplied from the inert gas supply unit. At this time, by appropriately adjusting the APC valve 243, a pressure in the reaction container 203 becomes a pressure within a range of 10 Pa to 1,000 Pa, for example. The temperature of the heater 218 is set to maintain the temperature of the substrate 200 to be within a range of 200° C. to 400° C., for example.

Specifically, when the valve 232d is opened, TSA gas is supplied from the first gas supply pipe 232a to the first processing region 201a through the first processing gas introduction instrument 251 and the first gas ejection port 254, and is exhausted through the first inert gas exhaust ports 259 and the first gas discharge instrument 261. At this time, by adjusting the supply and exhaust amounts of the TSA gas, a flow from the first gas ejection port 254 to the first inert gas exhaust ports 259 is formed, as shown in FIG. 4. That is, the TSA gas flows in a forward direction with respect to the rotation direction of the wafer 200.

By doing so, on the surface of the wafer 200, even in a place near to the center portion of the susceptor 217 and a place near the side end portion of the susceptor 217, it is possible to supply the TSA gas in a same flow rate with a center of the wafer, and thus supply the TSA gas uniformly to the surface of the wafer. By uniformly supplying the processing gas, it is possible to form a uniform film within the surface of the wafer.

The MFC 232c controls the flow rate of TSA gas to be within a predetermined range. Also, the MFC 232c controls the supply flow rate of TSA gas to be within a range of 100 sccm to 5,000 sccm, for example.

When supplying TSA gas into the first processing region 201a, the valve 235d is opened, and N₂ gas may be supplied as a carrier gas or a diluent gas from the second inert gas supply pipe 235a into the first processing region 201a. Therefore, the supply of TSA gas into the first processing region 201a can be facilitated.

Moreover, when the valve 233d is opened, oxygen gas is supplied from the second gas supply pipe 233a to the second processing region 201b through the second processing gas introduction instrument 252 and the second gas ejection port 255, and is exhausted through the second exhaust ports 260 and the second gas discharge pipe. At this time, by adjusting the supply and exhaust amounts of the oxygen gas, a flow from the second gas ejection port 255 to the second inert gas exhaust ports 260 is formed, as shown in FIG. 4. That is, the oxygen gas flows in a forward direction with respect to the rotation direction of the wafer 200.

By doing so, on the surface of the wafer 200, even in the place near to the center portion of the susceptor 217 and the place near the side end portion of the susceptor 217, it is possible to supply the oxygen gas in a same flow rate with the center of the wafer, and thus supply the oxygen gas uniformly to the surface of the wafer. By uniformly supplying the processing gas, it is possible to form a uniform film within the surface of the wafer.

At this time, the MFC 233c controls the flow rate of oxygen gas to be within a predetermined range. Also, the MFC 233c controls the supply flow rate of oxygen gas to be within a range of 1,000 sccm to 10,000 sccm, for example.

When supplying oxygen gas into the second processing region 201b, the valve 236d is opened, and N₂ gas may be supplied as a carrier gas or a diluent gas from the third inert gas supply pipe 236a into the second processing region 201b. Therefore, the supply of oxygen gas into the second processing region 201b can be facilitated.

Moreover, when the valves 232d, 233d and 234d are opened, N₂ gas (which is an inert gas as a purge gas) is supplied from the first inert gas supply pipe 234a to the first and second purge regions 204a and 204b through the inert gas introduction instrument 253, the first inert gas ejection port 256, and the second inert gas ejection port 257, and is exhausted. At this time, the MFC 234c controls the flow rate of N₂ gas to be within a predetermined range. Also, an inert gas is ejected in a direction from the first and second purge regions 204a and 204b to the first and second processing regions 201a and 201b, through a gap between the end portion of the partition plate 205 and the side wall of the reaction container 203. Therefore, a processing gas can be prevented from entering the first and second purge regions 204a and 204b.

When a gas supply is started, a high-frequency power source (not shown) supplies high-frequency power to the plasma generating unit 206 disposed in an upper side of the second processing region 201b. Oxygen gas, which is supplied into the second processing region 201b and passes through a portion under the plasma generating unit 206, is changed into a plasma state in the second processing region 201b, and thus, active species included in the plasma gas are supplied to the substrate 200.

Oxygen gas has a high reaction temperature, and it is difficult for oxygen gas to react under the processing temperature of the substrate 200 and the pressure in the reaction container 203 as described above. However, as in the first present embodiment, when oxygen gas is changed into a plasma state, the processing of film formation may be performed even at a temperature, for example, lower than or equal to 400° C. by supplying active species included in the plasma gas. Also, when a processing temperature required in the first processing gas differs from that required in the second processing gas, the heater 218 may be controlled based on a lower temperature of the processing temperatures of the first and second processing gases, and the other processing gas that requires a relatively higher processing temperature may be changed into a plasma state and supplied. As such, the substrate 200 may be processed at a low temperature by using the plasma state of the processing gas. By processing the substrate 200 at a low temperature, the substrate 200 (having an aluminum wiring vulnerable to heat, for example) can be prevented from being damaged due to heat. Also, the production of a foreign substance such as a product material due to the incomplete reaction of a processing gas can be prevented, and the uniformity or withstand voltage characteristic of a thin film that is formed on the substrate 200 can be enhanced. Also, due to the high oxidizing power of plasma-processed oxygen gas, an oxidization processing time can be shortened, and the productivity of substrate processing can be increased.

As described above, by rotating the susceptor 217, the substrate 200 is repeatedly moved through the first processing region 201a, the first purge region 204a, the second processing region 201b, and the second purge region 204b, in this order. Therefore, as shown in FIG. 7, the supply of TSA gas, the supply (purge) of N₂ gas, the supply of plasma-processed oxygen gas, and the supply (purge) of N₂ gas are alternately performed to the substrate 200 a predetermined number of times. According to the present invention, on the surface of the wafer 200, even in the place near to the center portion of the susceptor 217 and the place near the side end portion of the susceptor 217, the processing gas may be supplied in a same flow rate with the center of the wafer, thereby it is possible to supply the processing gas uniformly to the surface of the wafer. By uniformly supplying the processing gas, it is possible to form a uniform film within the surface of the wafer.

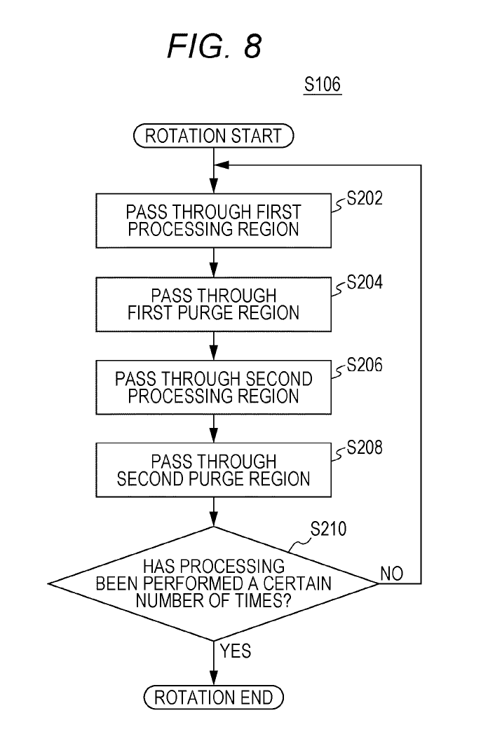

Herein, a specific example of the film forming sequence will be described with respect to FIG. 8.

(Passing Through First Processing Gas Region S202)

First, TSA gas is supplied to the surface of the substrate 200 that passes through the first processing region 201a, and a silicon-containing layer is uniformly formed on the substrate 200 in the center of the wafer, the place near to the center portion of the susceptor 217, and the place near the side end portion of the susceptor 217 thereof.

Then, the first processing gas introduction instrument 251 ejects a gas into the first processing region 201a toward the substrate from the first gas ejection port 254. The ejected gas is supplied to the wafer 200 passing though, thereby contributing to the formation of the silicon-containing layer on the wafer 200, and a gas that does not contribute to the forming is exhausted from the first exhaust ports 259.

(Passing Through First Purge Region S204)

Subsequently, the substrate 200 with the silicon-containing layer formed thereon passes through the first purge region 204a. At this time, N₂ gas as an inert gas is supplied to the substrate 200 passing through the first purge region 204a.

(Passing Through Second Processing Gas Region S206)

Subsequently, oxygen gas is uniformly supplied to the substrate 200 that has passed through the second processing region 201b in the center of the wafer, the place near to the center portion of the susceptor 217 and the place near the side end portion of the susceptor 217 thereof, and a silicon oxide layer (SiO layer) is uniformly formed on the substrate 200. That is, oxygen gas reacts with at least a portion of the silicon-containing layer that is formed on the substrate 200, in the first processing region 201a. Therefore, the silicon-containing layer is oxidized and thus modified into a SiO layer including silicon and oxygen. Furthermore, oxygen gas that does not contribute to a reaction is exhausted from the second exhaust ports 260.

(Passing Through Second Purge Region S208)

Then, the substrate 200, on which the SiO layer has been formed in the second processing region 201b, passes through the second purge region 204b. At this time, N₂ gas as an inert gas is supplied to the substrate 200 passing through the second purge region 204b.

(Confirming the Number of Cycle S210)

In this way, a SiO film may be formed with one rotation of the susceptor 217 as one cycle. That is, in one cycle, the substrate 200 has passed through the first processing region 201a, the first purge region 204a, the second processing region 201b, and the second purge region 204b. Thus, by performing the cycle at least one time or more, a SiO film having a predetermined film thickness may be formed on the substrate 200.

Herein, it is confirmed whether the above-described cycle has been performed a predetermined number of times.

When the cycle is performed a predetermined number of times, it is determined that the formed film has reached a desired film thickness, and the film forming process is completed. When the cycle is not performed a predetermined number of times, it is determined that the formed film has not reached a desired film thickness, and the sequence is returned to S202 to continue the cycle process.

In S210, after it is determined that the cycle has been performed a predetermined number of times, and an SiO film having a desired film thickness has been formed on the substrate 200, at least the valves 232d and 233d are closed, and supplying of the ISA gas to the first processing region 201a and supplying of the oxygen gas to the second processing region 201b are stopped. At this time, the supply of power to the plasma generating unit 206 is also stopped. In addition, a temperature is lowered or the supply of power to the heater 218 is stopped by controlling the flow of electricity to the heater 218. Furthermore, rotation of the susceptor 217 is stopped to end the film forming process.

(Substrate Unloading Process S108)

When the film forming process S106 is ended, the substrate is unloaded as follows.

The substrate lift pin 266 ascends, and the substrate 200 is supported on the substrate lift pin 266 that protrudes from the surface of the susceptor 217. Furthermore, the gate valve 151 is opened, and the first substrate transfer robot 112 unloads the substrate 200 to outside the reaction container 203, whereupon the substrate processing process according to the first embodiment is completed. Also, in the above description, conditions such as the temperature of the substrate 200, a pressure in the reaction container 203, the flow rate of each gas, power applied to the plasma generating unit 206, and a processing time, are appropriately adjusted based on the material or thickness of a film to be reformed.

### (4) Effects of the Present Embodiment

According to the first embodiment, at least one of the following effects (a) to (g) will now be described.

(a) Since, in at least one region of a plurality of the regions disposed in the process chamber, the processing gas flows from the upstream to the downstream in a rotation direction of the substrate, it is possible to uniformly supply a gas to the surface of the substrate. Therefore, it is possible to obtain a uniform thickness of the formed film within the surface of the substrate.

(b) Since the width of the gas ejection port is larger than the diameter of the substrate, it is possible for the entire surface of the substrate passing under the gas ejection port, to be supplied with the processing gas more uniformly and reliably.

(c) By adjusting the supply and exhaust amount of the reactant gas and/or non-reactant gas, it is possible to coincide the rotation direction of the susceptor 217 with a direction of the reactant gas flowing the processing region (the first or second processing region 201a or 201b). Therefore, a flow of the gas from the upstream to the downstream in a rotation direction of the substrate is formed in the processing region, and thus, it is possible to supply the processing gas more uniformly and reliably to the surface of the substrate.

(d) When the substrate is passing through the processing area, if the substrate is rotated in a direction from the gas supply unit to the gas exhaust unit, the substrate is processed, and if the substrate is rotated in a direction from the gas exhaust unit to the gas supply unit, the substrate is not processed. Accordingly, the first processing region 201a and the second processing region 201b is reliably separated, thus the quality of the film to be formed is maintained.

(e) The process chamber is divided into a plurality of predetermined regions, wherein the predetermined regions include a processing region to be supplied with the reactant gas and a non-processing region to be supplied with a non-reactant gas so as to form a non-reactant gas atmosphere, which are formed between the gas supply unit and the gas exhaust unit above the substrate mounting member, respectively, and the processing region is formed smaller than the non-processing region. Therefore, a flow of the gas from the upstream to the downstream in a rotation direction of the substrate is likely to be formed in the processing region, and thus, it is possible to supply the processing gas uniformly to the surface of the substrate.

(f) An angle between the gas supply unit and the gas exhaust unit forming the processing region is smaller than 90°. Therefore, a flow of the gas from the upstream to the downstream in a rotation direction of the substrate is likely to be formed in the processing region, and thus, it is possible to supply the processing gas uniformly to the surface of the substrate.

(g) By supplying the reactant gas into the processing region and the non-reactant gas into the non-processing region, it is controlled such that a flow of the gas from the upstream to the downstream in a rotation direction of the substrate is formed in the processing region, thereby it is possible to supply the processing gas more uniformly and reliably to the surface of the substrate.

### Another Embodiment of the Present Invention

An embodiment of the present invention has been described in detail, but the present invention is not limited to the above-described embodiment. The present invention may be variously modified within the scope that does not deviate from the subject matters of the present invention.

For example, in the above-described embodiment, the SiO film is formed on the substrate 200 by using a silicon-containing gas and an oxygen-containing gas as processing gases. However, the present invention is not limited thereto. That is, for example, high-k films such as a hafnium oxide (HfO) film, a zirconium oxide (ZrO) film, and a titanium oxide (TiO) film, may be formed by using a hafnium (Hf)-containing gas and an oxygen-containing gas, a zirconium (Zr)-containing gas and an oxygen-containing gas, and a titanium (Ti)-containing gas and an oxygen-containing gas. Also, in addition to an oxygen-containing gas, an ammonia (NH₃) gas that is nitrogen (N)-containing gas may be used as a processing gas that is changed into a plasma state.

In addition, in the above-described embodiment, although oxygen gas is supplied into the process chamber and plasma is generated in the plasma generating unit 206, it is not limited thereto, and, a remote plasma method that generates plasma outside of the process chamber or using ozone having a higher energy level may be applied.

Moreover, in the above-described embodiment, the inert gas introduction instrument 253 of the gas supply unit 250 is commonly used for the first and second purge regions 204a and 204b, but a plurality of inert gas introduction instruments may be separately provided in the first and second purge regions 204a and 204b. In addition, the inert gas introduction instrument may be disposed separately in first and second processing regions 201a and 201b, and first and second purge regions 204a and 204b, respectively. Thereby, since the flow rate of gas supplied into the respective regions may be controlled, for example, the inert gas may flow from the non-processing region to the processing region, so that a structure in which the reactant gas flows from the first gas ejection port 254 to the first exhaust ports 259 may be easily achieved.

Furthermore, in the above-described embodiment, the first gas ejection port 254 is disposed in the lower portion of the partition plate 205a, but the present invention is not limited thereto. It may be any structure in which a gas from the first gas ejection port 254 to the downstream in the rotational direction of the susceptor and, the gas may flow toward the gas ejection port on the downstream side, for example.

In addition, gas may be supplied using, for example, a nozzle, without providing the first exhaust ports 260 in the partition plate 205d. At that time, the partition structure to partition the region is not limited to the partition plate, and a partition structure that does not mix the processing gases may be separately provided.

In addition, in the above-described embodiment, although a plurality of first gas ejection ports 254 are disposed in the lower portion of the partition plate 205a, the present invention is not limited thereto, and the gas ejection port may have a slit shape. When the gas ejection port has the slit structure, a distance between end portions of the adjacent slits may be set in consideration of the width and position of the slit so as for the wafer 200 to pass through under between the end portions of the adjacent slits.

In addition, in the above-described embodiment, the second gas ejection port 255 is disposed in the lower portion of the partition plate 205c, but the present invention is not limited thereto. It may be any structure in which a gas flows from the second gas ejection port 255 to the downstream in the rotational direction of the susceptor and, the gas may flow toward the gas ejection port on the downstream side, for example.

In addition, gas may be supplied using, for example, a nozzle, without providing the first exhaust ports 260 in the partition plate 205d. At that time, the partition structure to partition the region is not limited to the partition plate, and a partition structure that does not mix the processing gases may be separately provided.

In addition, in the above-described embodiment, although a plurality of second gas ejection ports 255 are disposed in the lower portion of the partition plate 205c, the present invention is not limited thereto, and the gas ejection port may have a slit shape. When the gas ejection port has the slit structure, a distance between end portions of the adjacent slits may be set in consideration of the width and position of the slit so as for the wafer 200 to pass through under between the end portions of the adjacent slits.

Moreover, in the above-described embodiment, the first exhaust port 259 is disposed in the partition plate 205b, but the present invention is not limited thereto. It may be any structure capable of sucking a gas flowing from the upstream in the rotation direction of the substrate by the first gas exhaust ports 259 and, the gas may flow toward the gas ejection port on the upstream side, for example.

Moreover, it may be also possible to provide an exhaust structure exclusive for exhausting. As an example of the exhaust structure exclusive for exhausting, a slit-shaped exhaust port may be used to exhaust gas. At that time, the partition structure to partition the region is not limited to the partition plate, and a partition structure that does not mix the processing gases may be separately provided.

Moreover, in the above-described embodiment, the second exhaust ports 260 are disposed in the lower portion of the partition plate 205d, but the present invention is not limited thereto. It may be any structure capable of sucking a gas flowing from the upstream in the rotation direction of the substrate by the second gas exhaust ports 260 and, the gas may flow toward the gas ejection port on the upstream side, for example.

Furthermore, in the above-described embodiment, although the second exhaust ports 260 are disposed in the partition plate 205d, the present invention is not limited thereto, and it may be also possible to provide an exhaust structure exclusive for exhausting. As an example of the exhaust structure exclusive for exhausting, a slit-shaped exhaust port may be used to exhaust gas. At that time, the partition structure to partition the region is not limited to the partition plate, and a partition structure that does not mix the processing gases may be separately provided.

Furthermore, in the above-described embodiment, the gas flow direction is formed in the rotation direction of the substrate, but the present invention is not limited thereto. The gas may flow in a direction opposite to the rotation direction of the substrate depending on the quality of gas supplied or rotation situation of the susceptor.

Moreover, in the above-described embodiment, the supply and exhaust amounts of the reactant gas are controlled, but the present invention is not limited thereto. For example, the exhaust amount of the gas exhaust unit (the first and second exhaust ports 259 and 260) may be larger than that of the exhaust pipe 231.

Hereinafter, some aspects of the present invention will be additionally stated.

(Supplementary Note 1)

A substrate processing apparatus includes: a process chamber having a plurality of regions; a substrate mounting member which is disposed in the process chamber and includes a mounting surface which is configured to concentrically mount a plurality of substrates and faces a ceiling of the process chamber; a rotation instrument configured to rotate the substrate mounting member in a direction parallel to the mounting surface; a gas supply unit disposed in the process region above the substrate mounting member upstream in a rotation direction of the substrate mounting member; and a gas exhaust unit disposed in the process region above the substrate mounting member downstream in the substrate mounting member rotating direction.

(Supplementary Note 2)

In the apparatus of supplementary note 1, the gas supply unit has a gas ejection port, and a width of the gas ejection port is larger than that of the substrate.

(Supplementary Note 3)

In the apparatus of supplementary note 1 or 2, the region is a region into which a reactant gas is supplied and a region into which a non-reactant gas is supplied, and a region into which the reactant gas is supplied is formed between the gas ejection port and a gas exhaust port disposed in the gas exhaust unit.

(Supplementary Note 4)

A substrate processing apparatus includes: a process chamber having a plurality of regions; a substrate mounting member which is disposed in the process chamber and includes a mounting surface which is configured to concentrically mount a plurality of substrates and faces a ceiling of the process chamber; a rotation instrument configured to rotate the substrate mounting member in a direction parallel to the mounting surface; a plurality of partition parts configured to partition the region; a gas ejection port disposed in the partition parts; and a gas exhaust port disposed downstream in a rotation direction of the partition parts.

(Supplementary Note 5)

In the apparatus of supplementary note 4, the partition parts are radially formed.

(Supplementary Note 6)

A method of manufacturing a semiconductor device includes: concentrically mounting a plurality of substrates on a substrate mounting member disposed in a substrate process chamber with a plurality of partitioned regions; rotating the plurality of the concentrically mounted substrates; and supplying a gas from a gas supply unit which is disposed at a position facing the substrate mounting member upstream in a rotation direction of the substrate, and exhausting the gas from a gas exhaust unit which is disposed at a position facing the substrate mounting member downstream in the rotation direction of the substrate to process the substrates.

(Supplementary Note 7)

A method of manufacturing a semiconductor device includes: concentrically mounting a plurality of substrates on a substrate mounting member disposed in a substrate process chamber with a plurality of regions partitioned by partition parts; rotating the plurality of the concentrically mounted substrates; and supplying a gas from a partition part disposed upstream in a rotation direction of the substrate, and exhausting the gas from a partition part disposed downstream in the rotation direction of the substrate to process the substrates.

(Supplementary Note 8)

A substrate processing apparatus includes: a process chamber configured to process a substrate; a substrate mounting member including a mounting surface which is configured to concentrically mount a plurality of substrates and faces a ceiling of the process chamber; a rotation instrument configured to rotate the substrate mounting member in a direction parallel to the mounting surface; a gas supply unit disposed in the process chamber above the substrate mounting member upstream in a rotation direction of the substrate mounting member; a gas exhaust unit disposed in the process chamber above the substrate mounting member downstream in the substrate mounting member rotating direction; and a controller configured to control the gas supply unit, the gas exhaust unit, and the rotation instrument so as to process the substrates, when the substrate passes through a predetermined region formed in the process chamber by the gas supply unit and the gas exhaust unit, by supplying a reactant gas from the gas supply unit and exhausting the reactant gas from the gas exhaust unit.

(Supplementary Note 9)

In the apparatus of supplementary note 8, when the substrate passes through the predetermined region, the substrate rotated in a direction from the gas supply unit to the gas exhaust unit is processed and the substrate rotated in a direction from the gas exhaust unit to the gas supply unit is not processed.

(Supplementary Note 10)

In the apparatus of supplementary note 9, the predetermined region includes a processing region to which the reactant gas is supplied and a non-processing region to which a non-reactant gas is supplied so as to form a non-reactant gas atmosphere, which are formed between the gas supply unit and the gas exhaust unit above the substrate mounting member, respectively, and the processing region is formed smaller than the non-processing region.

(Supplementary Note 11)

In the apparatus of supplementary note 10, an angle between the gas supply unit and the gas exhaust unit forming the processing region is smaller than 90°, and an angle between the gas exhaust unit and the gas supply unit forming the non-processing region is larger than 90°.

(Supplementary Note 12)

In the apparatus of supplementary note 10 or 11, a direction in which the reactant gas flows through the processing region is the same as the rotation direction of the substrate mounting member on which the substrate is mounted.

(Supplementary Note 13)

In the apparatus of supplementary note 10 or 11, at least the reactant gas is supplied to the processing region and the non-reactant gas is supplied to the non-processing region so as to exhaust the reactant gas and the non-reactant gas from the gas exhaust unit.

(Supplementary Note 14)

In the apparatus of supplementary note 8, the controller is configured to adjust a supply amount and exhaust amount of the reactant gas, when the substrate passes through the predetermined region formed in the process chamber, so as to form a flow of the reactant gas in a forward direction with respect to the rotation direction of the substrate.

(Supplementary Note 15)

The apparatus of supplementary note 14 further includes an exhaust pipe disposed under the process chamber to exhaust the gas from the non-processing region, wherein the controller controls such that the exhaust amount from the gas exhaust unit is larger than the exhaust amount from the exhaust pipe.

(Supplementary Note 16)

A method of manufacturing a semiconductor device includes: concentrically mounting a plurality of substrates on a substrate mounting member disposed in a process chamber with a plurality of partitioned regions; rotating the plurality of the concentrically mounted substrates; and in a region in which a gas flow direction from the gas supply unit to the gas exhaust unit is the same as the rotation direction of the substrate mounting member, supplying a reactant gas from a gas supply unit which is disposed at a position facing the substrate mounting member upstream in a rotation direction of the substrate mounting member, and exhausting the reactant gas from a gas exhaust unit which is disposed at a position facing the substrate mounting member downstream in the rotation direction of the substrate mounting member to process the substrates.

(Supplementary Note 17)

A method of supplying and exhausting gas includes: concentrically mounting a plurality of substrates on a substrate mounting member disposed in a process chamber with a plurality of partitioned regions; rotating the plurality of the concentrically mounted substrates; and in a region in which a gas flow direction from the gas supply unit to the gas exhaust unit is the same as the rotation direction of the substrate mounting member, supplying a reactant gas from a gas supply unit which is disposed at a position facing the substrate mounting member upstream in a rotation direction of the substrate mounting member, and exhausting the reactant gas from a gas exhaust unit which is disposed at a position facing the substrate mounting member downstream in the rotation direction of the substrate mounting member.

What is claimed is:

1. A substrate processing apparatus, comprising:
a process chamber configured to process a substrate;
a substrate mounting member including amounting surface which is configured to concentrically mount a plurality of substrates and faces a ceiling of the process chamber;
a rotation instrument configured to rotate the substrate mounting member in a direction parallel to the mounting surface;
a gas supply unit disposed in the process chamber above the substrate mounting member upstream in a rotation direction of the substrate mounting member;
a gas exhaust unit disposed in the process chamber above the substrate mounting member downstream in the substrate mounting member rotating direction; and
a controller configured to control the gas supply unit, the gas exhaust unit, and the rotation instrument so as to process the substrate, when the substrate passes through a predetermined region formed in the process chamber by the gas supply unit and the gas exhaust unit, by supplying a reactant gas from the gas supply unit and exhausting the reactant gas from the gas exhaust unit.

2. The apparatus of claim 1, wherein, when the substrate passes through the predetermined region, the substrate rotated in a direction from the gas supply unit to the gas exhaust unit is processed and the substrate rotated in a direction from the gas exhaust unit to the gas supply unit is not processed.

3. The apparatus of claim 1, wherein the predetermined region includes a processing region to which the reactant gas is supplied and a non-processing region to which a non-reactant gas is supplied so as to form a non-reactant gas atmosphere, which are formed between the gas supply unit and the gas exhaust unit above the substrate mounting member, respectively, and the processing region is formed smaller than the non-processing region.

4. The apparatus of claim 3, wherein an angle between the gas supply unit and the gas exhaust unit forming the processing region is smaller than 90°, and an angle between the gas exhaust unit and the gas supply unit forming the non-processing region is larger than 90°.

5. The apparatus of claim 3, wherein a direction in which the reactant gas flows through the processing region is the same as the rotation direction of the substrate mounting member on which the substrate is mounted.

6. The apparatus of claim 3, wherein at least the non-reactant gas is supplied to the non-processing region so as to flow the reactant gas and the non-reactant gas in the processing region, and at least the reactant gas is exhausted from the gas exhaust unit.

7. The apparatus of claim 1, wherein the controller is configured to adjust a supply amount and exhaust amount of the reactant gas, when the substrate passes through the predetermined region formed in the process chamber, so as to form a flow of the reactant gas in a forward direction with respect to the rotation direction of the substrate.

8. The apparatus of claim 3, further comprising an exhaust pipe disposed under the process chamber to exhaust the gas from the non-processing region, wherein the controller controls such that the exhaust amount from the gas exhaust unit is larger than the exhaust amount from the exhaust pipe.

9. The apparatus of claim 3, further comprising an exhaust pipe disposed under the process chamber to exhaust the gas from the non-processing region, wherein the controller controls such that the reactant gas is exhausted from the gas exhaust unit and the non-reactant gas is exhausted from the exhaust pipe.

10. A method of supplying and exhausting gas in a substrate processing apparatus including:
a process chamber configured to process a substrate;
a substrate mounting member including amounting surface which is configured to concentrically mount a plurality of substrates and faces a ceiling of the process chamber;
a rotation instrument configured to rotate the substrate mounting member in a direction parallel to the mounting surface;
a gas supply unit disposed in the process chamber above the substrate mounting member upstream in a rotation direction of the substrate mounting member;
a gas exhaust unit disposed in the process chamber above the substrate mounting member downstream in the substrate mounting member rotating direction; and
a controller configured to control the gas supply unit, the gas exhaust unit, and the rotation instrument, the method comprising:
when the substrate passes through a predetermined region formed in the process chamber by the gas supply unit and the gas exhaust unit, controlling the reactant gas supplied from the gas supply unit to form a flow exhausting from the gas exhaust unit, in the predetermined region in which a gas flow direction from the gas supply unit to the gas exhaust unit is the same as the rotation direction of the substrate mounting member.
